(19) United States
(12) Patent Application Publication
(10) Pub. No.: US 2015/0214207 A1
(43) Pub. Date: Jul. 30, 2015

(54) CHIP STACK, SEMICONDUCTOR DEVICES HAVING THE SAME, AND MANUFACTURING METHODS FOR CHIP STACK

(71) Applicant: PS4 Luxco S.a.r.l., Luxembourg (LU)

(72) Inventor: Masanori Yoshida, Tokyo (JP)

(73) Assignee: PS4 Luxco S.a.r.l., Luxembourg (LU)

(21) Appl. No.: 14/424,437

(22) PCT Filed: Aug. 21, 2013
(86) PCT No.: PCT/JP2013/072926

§ 371 Date: Feb. 26, 2015

(30) Foreign Application Priority Data
Aug. 27, 2012 (JP) 2012-186632
Feb. 25, 2013 (JP) 2013-034406

(51) Int. Cl. H01L 25/00; H01L 21/56; H01L 23/00; H01L 23/498; H01L 25/18; H01L 25/065

(52) U.S. Cl. CPC H01L 25/50; H01L 25/18; H01L 25/0657; H01L 24/81; H01L 23/49838; H01L 21/56; H01L 2225/06513; H01L 2225/06517; H01L 2225/0652; H01L 2225/06555; H01L 2224/16113; H01L 2224/16145; H01L 2224/16225; H01L 2224/81801; H01L 2924/1431; H01L 2924/1434

(57) ABSTRACT

A chip stack (11) is configured by stacking at least first, second, and third semiconductor chips (10a, 10b, 10c). The first semiconductor chip (10a) has bump electrodes formed only on one side thereof. The second semiconductor chip (10b) has bump electrodes formed on both sides thereof and they are electrically connected each other. The second semiconductor chip (10b) is stacked on and electrically connected to the first semiconductor chip (10a) through a first solder layer. The third semiconductor chip (10c) has bump electrodes formed on both sides thereof and they are electrically connected each other. Second and third solder layers are formed on the bump electrodes on the both sides of the third semiconductor chip. The third semiconductor chip (10c) is stacked on and electrically connected to the second semiconductor chip (10b) through the third solder layer.

This application is based upon and claims the benefit of priority from Japanese patent application No. 2012-186632, filed on Aug. 27, 2012 and Japanese patent application No. 2013-034404, filed on Feb. 25, 2013, the disclosure of which is incorporated herein in its entirety by reference.

### TECHNICAL FIELD

The present invention relates to a CoC (Chip on Chip) type semiconductor devices and manufacturing methods for the same.

### BACKGROUND ART

In recent years, as electronic devices have been miniaturized and have come with advanced functions, CoC type semiconductor devices which is configured by stacking a plurality of semiconductor chips each having through-electrode, such as through-silicon via (hereafter, referred to as TSV), have been proposed.

As an example of such semiconductor devices, JP2010-251347A Publication (hereinafter referred to as Patent Literature 1) discloses technologies as follows: a plurality of semiconductor chips each having TSV are stacked so that they are connected by each TSV, and then the peripheries of the stacked semiconductor chips are coated by a sealing resin layer in order to fill spaces between adjacent semiconductor chips, and therefore, a chip stack is manufactured. After it has been manufactured, the chip stack may be mounted on a wiring board.

In such a CoC type semiconductor device, bumps of a plurality of semiconductor chips are respectively connected through a solder layer in order to ensure the reliability of their connections of the chip stack. In case in which bumps are connected at a temperature above the solder melting temperature, bumps are formed on the front surface of each of the semiconductor chips that are held on a bonding tool, but a solder layer is not formed on these bumps for the purpose of preventing the solder from adhering to the bonding tool. A solder layer is formed only on bumps that are formed on the rear surface of each of the semiconductor chips. Bumps(Ni/Au bumps) that are formed on each of semiconductor chips are formed as a result of an Ni plating layer and an Au plating layer being successively formed on Cu pillars.

After such semiconductor chips are prepared, the rear surface of a first semiconductor chip of the prepared semiconductor chips is adhered to an adsorption stage, the front surface of a second semiconductor chip is held by the bonding tool. And then, bumps on the rear surface of the second semiconductor chip are connected to bumps on the front surface of the first semiconductor chip that is adhered on the adsorption stage, through the solder layer of the bumps on the rear surface of the second semiconductor device.

When a chip stack is manufactured by stacking a plurality of semiconductor chips in the manner as above, the front surface of the uppermost semiconductor chip becomes a surface having bumps on which a solder layer is not formed. On the other hand, since the rear surface of the lowermost semiconductor chip of the chip stack is a surface that comes in contact with the adsorption stage, the rear surface of the lowermost semiconductor chip also becomes a surface having bumps on which a solder layer is not formed.

Therefore, if the chip stack is connected by the flip-chip bonding method on the rear surface of a semiconductor chip that has been mounted on a wiring board by the flip-chip bonding method, the rear surface of the lowermost semiconductor chip, having bumps on which a solder layer is not formed, will be used as a surface held by the bonding tool. However, a surface of the chip stack, to which bumps on the semiconductor chip mounted on the wiring board are connected, will become the front surface of the uppermost semiconductor chip having bumps on which a solder layer is not formed. In this case, since there is no solder layer between Ni/Au bumps, it will be difficult to connect between the bumps.

From the foregoing point of view, it has been considered that a solder layer is formed on bump electrodes that are arranged on the front surface of the uppermost semiconductor chip of the chip stack. However, it was difficult to form a solder layer on small bumps of the chip stack composed of a plurality of semiconductor chips, by means of plating, printing, and the like after the chip stack has been manufactured.

In addition, as described in Patent Literature 1, in a case in which bump electrodes on each of a plurality of semiconductor chips that are stacked on a wiring board are at the same location, TSVs of each semiconductor chip will be arranged on the straight in a state of a chip stack. In such a chip stack, temperature changes in the manufacturing process of the chip stack cause the TSVs to expand and shrink, resulting in stress imposed thereon. The highest stress is imposed on the TSVs of a semiconductor chip that is disposed the furthest apart from the wiring board. Consequently, it is likely that the semiconductor chip will crack.

### SUMMARY OF INVENTION

In one embodiment, there is provided a chip stack that is configured by stacking a plurality of semiconductor chips, wherein a plurality of bump electrodes are formed at the same locations of each semiconductor chip.

The chip stack is configured by stacking in sequence at least a first semiconductor chip, a second semiconductor chip, and a third semiconductor chip.

The first semiconductor chip comprises a plurality of first bump electrodes that are formed on a first surface thereof, but bump electrodes are not formed on a second surface of the first semiconductor chip.

The second semiconductor chip comprises a plurality of second bump electrodes that are formed on a first surface thereof, and a plurality of third bump electrodes that are formed on a second surface thereof and that are electrically connected to the plurality of second bump electrodes, respectively. The second semiconductor chip is stacked on the first semiconductor chip. The plurality of third bump electrodes are electrically connected to the plurality of first bump electrodes through a first solder layer, respectively.

The third semiconductor chip comprises a plurality of fourth bump electrodes that are formed on a first surface thereof, a plurality of a second solder layer that are formed on the plurality of fourth bump electrodes, respectively, and a plurality of fifth bump electrodes that are formed on a second surface thereof and that are electrically connected to the plurality of fourth bump electrodes, respectively. The third semiconductor chip is stacked on the second semiconductor chip. The plurality of fifth bump electrodes are electrically connected to the plurality of second bump electrodes through a third solder layer, respectively.

In the chip stack of this aspect, temperature changes in the manufacturing process of the chip stack cause TSVs of each semiconductor chip to expand and shrink, which results in stress being imposed thereon. If the chip stack according to this aspect is connected by the flip-chip bonding method on the rear surface of a semiconductor chip that has been mounted on a wiring board by the flip-chip bonding method, the surface of the chip stack, which is connected with bumps electrodes of the semiconductor chip mounted on the wiring board, becomes a surface having bump electrodes (namely, the fourth bump electrodes of the third semiconductor chip) on which a solder layer was formed. Thus, the first semiconductor chip that does not have TSVs and rear surface bumps is disposed the furthest apart from the wiring board. As a result, the foregoing stress is imposed on the surface that does not have TSVs of the first semiconductor chip. Therefore, a semiconductor device that prevents occurrence of chip cracks and has high reliability can be provided.

In another embodiment, there is provided a manufacturing method for a semiconductor device comprising: a chip stack that is configured by stacking at least a first semiconductor chip, a second semiconductor chip, and a third semiconductor chip, wherein a plurality of bump electrodes are formed at the same locations of each semiconductor chip; a fourth semiconductor chip; and a wiring board on which the fourth semiconductor chip is mounted on a first surface thereof and the chip stack is stacked on the fourth semiconductor chip.

This manufacturing method comprises: preparing the first, second, and third semiconductor chips; preparing the fourth semiconductor chip that comprises a plurality of sixth bump electrodes formed on a first surface thereof and a plurality of seventh bump electrodes that are formed on a second surface thereof and are electrically connected to the plurality of sixth bump electrodes respectively; and preparing a wiring board that can connect the plurality of sixth bump electrodes of the fourth semiconductor chip on a first surface thereof.

In addition, this method further comprises:

placing the first semiconductor chip on a flat stage such that the first surface of the first semiconductor chip faces upward;

stacking the second semiconductor chip on the first semiconductor chip so that the plurality of third bump electrodes are electrically connected to the plurality of first bump electrodes through the first solder layer, respectively;

stacking the third semiconductor chip on the second semiconductor chip such that the plurality of fifth bump electrodes are electrically connected to the plurality of second bump electrodes through the third solder layer, respectively;

mounting the fourth semiconductor chip on the wiring board so that the plurality of sixth bump electrodes are electrically connected to the wiring board; and

stacking the chip stack that is configured by stacking the first semiconductor chip, the second semiconductor chip, and the third semiconductor chip, on the fourth semiconductor chip mounted on the wiring board, so that the plurality of fourth bump electrodes are electrically connected to a part or all of the plurality of seventh bump electrodes through the second solder layer, respectively.

In such a manufacturing method, if the chip stack is connected by the flip-chip bonding method on the rear surface of a semiconductor chip that has been mounted on a wiring board by the flip-chip bonding method, a surface of the chip stack, which is connected with bumps electrodes of the semiconductor chip mounted on the wiring board, becomes a surface having bump electrodes on which a solder layer was formed. Therefore, since there will be a solder layer between bump electrodes, it can be successfully connected between the bumps.

In addition, chips are stacked in such a state that bump electrodes on the third semiconductor chip, which are connected to bump electrodes on the fourth semiconductor chip mounted on the wiring board, are placed in the concave parts formed in the bonding stage. Because of this, when the chip stack is manufactured, the bump electrodes on the third semiconductor chip do not collapse. As a result, the reliability of bump connections improves.

In the case in which an insulation resin adhesive film (NCP) has been formed on the rear surface of each of the second semiconductor chip and the third semiconductor chip that compose the chip stack, the space between the first semiconductor chip and the second semiconductor chip and the space between the second semiconductor chip and the third semiconductor chip can be filled with the NCP when the chip stack is manufactured. Consequently, the manufacturing process of the semiconductor device can be simplified compared to the method which uses an under-fill material. In addition, since the amount of insulation resin that coats the chip stack can be reduced, stress caused by hardening shrinkage imposed on the chip stack can be reduced.

As described above, according to the aspects of the present invention, a chip stack having high reliability, which is satisfactorily connected to a semiconductor chip mounted on a wiring board by the flip-chip bonding method, can be obtained.

### BRIEF DESCRIPTION OF DRAWINGS

The above features and advantages of the present invention will be more apparent from the following description of certain preferred embodiments taken in conjunction with the accompanying drawings, in which:

FIG. 1 is a sectional view showing an outline of the structure of a semiconductor device according to a first embodiment of the present invention;

FIG. 2(a) to FIG. 2(d) are sectional views showing an outline of the structures of a plurality of semiconductor chips that comprise a chip stack according to the first embodiment of the present invention;

FIG. 3 is an enlarged view showing an outline of the structure of essential parts of a third semiconductor chip shown in FIG. 2(a);

FIG. 4(a) to FIG. 4(d) are sectional views showing an example of an assembling procedure of the chip stack shown in FIG. 1;

FIG. 5(a) to FIG. 5(c) are sectional views showing an example of an assembling procedure of the chip stack shown in FIG. 1;

FIG. 6(a) to FIG. 6(e) are sectional views showing an example of an assembling procedure of a semiconductor device using the chip stack shown in FIG. 1;

FIG. 7 is a sectional view showing a modification of the semiconductor device according to the first embodiment;

FIG. 8 is a sectional view showing an outline of the structure of a semiconductor device according to a second embodiment of the present invention;

FIG. 9(a) to FIG. 9(d) are sectional views showing an outline of the structures of a plurality of semiconductor chips that comprise a chip stack according to the second embodiment of the present invention;

FIG. 10(a) to FIG. 10(d) are sectional views showing a manufacturing process of the chip stack shown in FIG. 8;

FIG. 11(a) to FIG. 11(e) are sectional views showing an example of an assembling procedure of the semiconductor device using the chip stack shown in FIG. 8; and

FIG. 12(a) to FIG. 12(c) are sectional views showing manufacturing steps of a semiconductor chip having an NCF layer as shown in FIG. 9.

### DESCRIPTION OF EMBODIMENTS

The invention will be now described herein with reference to illustrative embodiments. Those skilled in the art will recognize that many alternative embodiments can be accomplished using the teachings of the present invention and that the invention is not limited to the embodiments that are used for explanatory purposes.

### First Embodiment

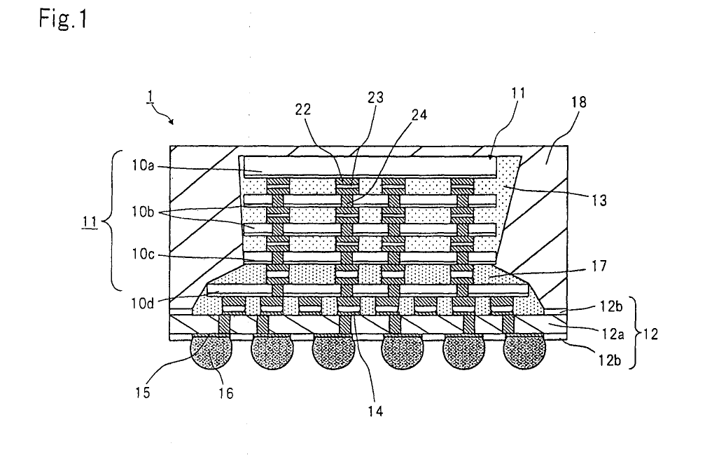

In semiconductor device 1 according to a first embodiment of the present invention shown in FIG. 1, chip stack 11 is composed of a plurality of memory chips (first semiconductor chip 10a, two second semiconductor chips 10b, and third semiconductor chip 10c). Chip stack 11 is mounted on a logic chip (fourth semiconductor chip 10d) mounted on wiring board 12.

Chip stack 11 is composed of a plurality of memory chips (in this example, semiconductor chips 10a to 10c). A memory circuit and a plurality of bump electrodes are formed on one surface of each of the memory chips. The structures of the memory circuits of the memory chips are substantially the same. The locations of the bump electrodes formed on one surface of each of the memory chips are substantially the same. In addition, the memory chips (semiconductor chips 10a to 10c) that comprise chip stack 11 are three types of memory chips that have substantially the same memory circuits but slightly different structures and that perform substantially the same operations. As will be described in manufacturing steps for chip stack 11, first semiconductor chip 10a is located at the lowermost position, two second semiconductor chips 10b are stacked on first semiconductor chip 10a, and third semiconductor chip 10c that is located at the uppermost position is stacked on second semiconductor chips 10b.

In addition, chip stack 11 is provided with first sealing resin layer 13 that fills spaces between adjacent chips of semiconductor chips 10a to 10d and that has a generally trapezoidal cross section when viewed from the side. First sealing resin layer 13 is made, for example, of a known under-fill material. The uppermost semiconductor chip 10c that is disposed on a short (upper bottom) side of generally trapezoidal wiring board 12 is connected to fourth semiconductor chip 10d mounted on wiring board 12. Thus, third semiconductor chip 10c is disposed at the lowermost position in semiconductor device 1 shown in FIG. 1.

Wiring board 12 is composed of insulation substrate 12a (for example, a glass epoxy substrate) that has wirings (not shown) formed on both surfaces of the wiring board. Except for connection pads 14 and lands 15 that will be described later, each wiring on insulation substrate 12a is coated with insulation film 12b, such as a solder resist film.

Formed on one surface of wiring board 12 are a plurality of connection pads 14 to be connected to fourth semiconductor chip 10d. Formed on the other surface of wiring board 12 are a plurality of lands 15 to be connected to solder balls 16 that become external terminals. Connection pads 14 are connected to predetermined lands 15 through the wirings. Lands 15 are formed on the other surface of wiring board 12 at predetermined intervals, for example, in a grid shape.

A space between chip stack 11 and fourth semiconductor chip 10d and a space between fourth semiconductor chip 10d and wiring board 12 are filled up with an under-fill material. The under-fill material securely adheres to chip stack 11 and wiring board 12 and protects electrode connections. The under-fill material becomes second sealing resin layer 17.

In addition, chip stack 11 and fourth semiconductor chip 10d that are mounted on wiring board 12 are sealed with third sealing resin layer 18. Solder balls 16 that become the external terminals of semiconductor device 1 are connected to the plurality of lands 15 that are formed on the other surface of wiring board 12 on which chip stack 11 is not mounted.

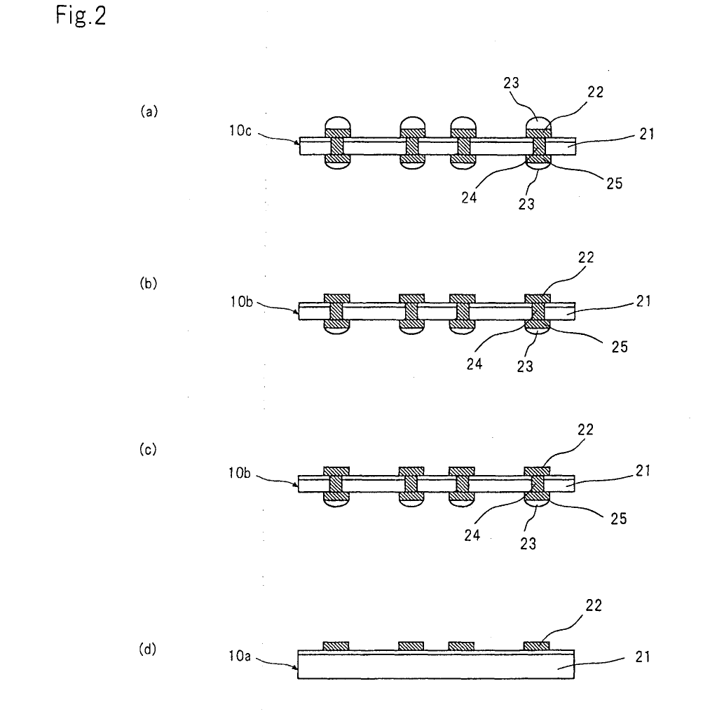

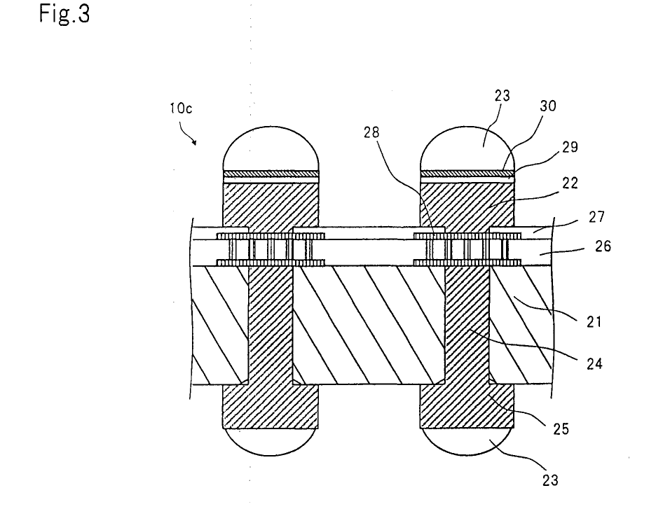

FIGS. 2(a) to 2(d) are sectional views showing an outline of the structures of the plurality of semiconductor chips 10a to 10c that comprise chip stack 11. FIG. 3 is an enlarged view showing an outline of the structure of essential parts of third semiconductor chip 10c.

As described above, chip stack 11 is composed such that two second semiconductor chips 10b are stacked on first semiconductor chip 10a and then third semiconductor chip 10c is stacked thereon.

As shown in FIG. 2(a) and FIG. 3, in third semiconductor chip 10c (memory chip), a predetermined memory circuit is formed on one surface of silicon board 21. On one surface of silicon board 21, a plurality of electrode pads that are electrically connected to the memory circuit are arranged at predetermined locations. In order to protect a surface on which a circuit is formed, insulating protection film 27 is formed on circuit layer 26 on which the foregoing memory circuit is formed. Formed on protection film 27 are openings that expose electrode pads 28. Formed on one surface of silicon board 21 are a plurality of front bumps 22 that are respectively formed on the plurality of electrode pads 28. Front bumps 22 are pillars made of Cu, for example and that protrude from the front surface of the semiconductor chip. Formed on front bumps 22 are Ni plating layer 29 that prevents Cu from dispersing and Au plating layer 30 that prevents front bumps 22 from being oxidized.

In third semiconductor chip 10c, solder layer 23 made of Sn/Ag is formed on Au plating layer 30. When solder layer 23 made of Sn/Ag is reflowed, solder layer 23 is temporarily melted and thereby solder layer 23 is formed in a semispherical shape on front bumps 22.

Formed on silicon board 21 are also via holes corresponding to the electrode pads. The via holes are filled with a conductor material, for example Cu, so as to form through-silicon vias (TSVs) 24.

Formed on the other surface of silicon board 21 are a plurality of rear bumps 25. The plurality of rear bumps 25 are electrically connected to front bumps 22 through TSVs 24, respectively. Rear bumps 25 are pillars made of Cu, for example, and protrude from the rear surface of the semiconductor chip. Formed on the front surface of rear bumps 25 is solder layer 23 made of Sn/Ag. Likewise, solder layer 23 on the rear surface of the semiconductor chip is formed in a semispherical shape on rear bumps 25.

The thickness of solder layer 23 made of Sn/Ag, formed on front bumps 22, is greater than that of solder layer 23 made of Sn/Ag, formed on rear bumps 25. For example, the thickness of solder layer 23 formed on the front surface of the semiconductor chip is 10 μm or greater, and the thickness of solder layer 23 on the rear surface of the semiconductor chip is 7.5 μm. According to this thickness relationship, the reliability of the connections to bumps of another type of semiconductor chip (fourth semiconductor chip 10d) such as a logic chip can be improved.

Second semiconductor chip 10b (memory chip) is substantially the same as third semiconductor chip 10c. As shown in FIG. 2(b) and FIG. 2(c), in second semiconductor chip 10b, a plurality of front bumps 22 are formed on one surface of silicon board 21 and a plurality of rear bumps 25 are formed on the other surface of silicon board 21 such that rear bumps 25 are electrically connected to front bumps 22 through TSVs 24. Formed on rear bumps 25 is solder layer 23 made of Sn/Ag.

Thus, second semiconductor chip 10b is different from third semiconductor chip 10c in that solder layer 23 is not formed on front bumps 22 of third semiconductor chip 10c shown in FIG. 3. Second semiconductor chip 10b can be manufactured in the same manufacturing process as third semiconductor chip 10c by not performing such a process in which Sn/Ag solder plating is formed on front bumps 22 of third semiconductor chip 10c. The thickness of solder layer 23 on the rear surface of second semiconductor chip 10b is, for example, 7.5 μm, which is the same as the thickness of solder layer 23 formed on the rear surface of third semiconductor chip 10c.

In the chip stack according to this embodiment, two second semiconductor chips 10b are stacked. Alternatively, in the chip stack according to this embodiment, one second semiconductor chip 10b or three or more second semiconductor chips 10b may be stacked.

First semiconductor chip 10a (memory chip) is substantially the same memory chip as third semiconductor chip 10c. As shown in FIG. 2(d), in first semiconductor chip 10a, a plurality of front bumps 22 are formed on one surface of silicon board 21. However, first semiconductor chip 10a does not have TSVs that pierce silicon board 21, besides, rear surface bumps are formed on the other surface of silicon board 21. While the thickness of first semiconductor chip 10a is, for example, 100 μm, the thickness of each of second semiconductor chip 10b and third semiconductor chip 10c is, for example, 50 μm. Thus, the thickness of first semiconductor chip 10a is greater than the thickness of each of second semiconductor chip 10b and third semiconductor chip 10c.

Therefore, the structure of first semiconductor chip 10a is different from the structure of third semiconductor chip 10c in that a solder layer is not formed on front bumps 22, TSVs are not formed in via holes that pierce silicon board 21, and rear surface bumps are not formed. First semiconductor chip 10a can be manufactured in the same manufacturing process as first semiconductor chip 10a by not performing such a process in which TSVs and rear surface bumps are formed on silicon board 21.

Next, assembling steps of chip stack 11 will be described.

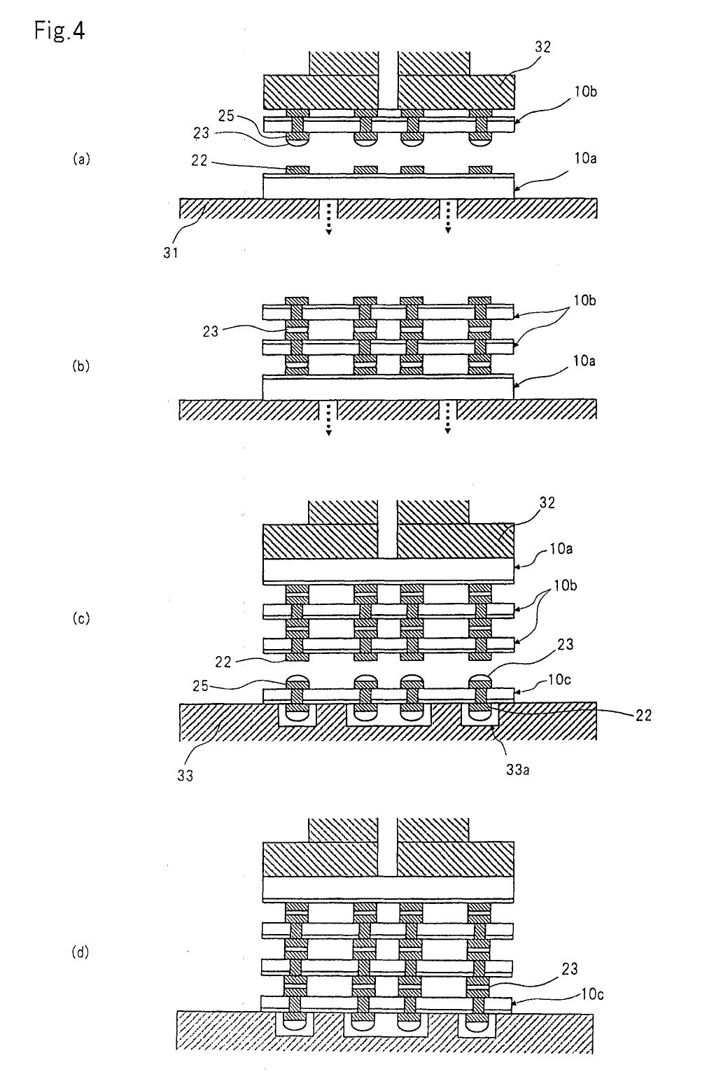

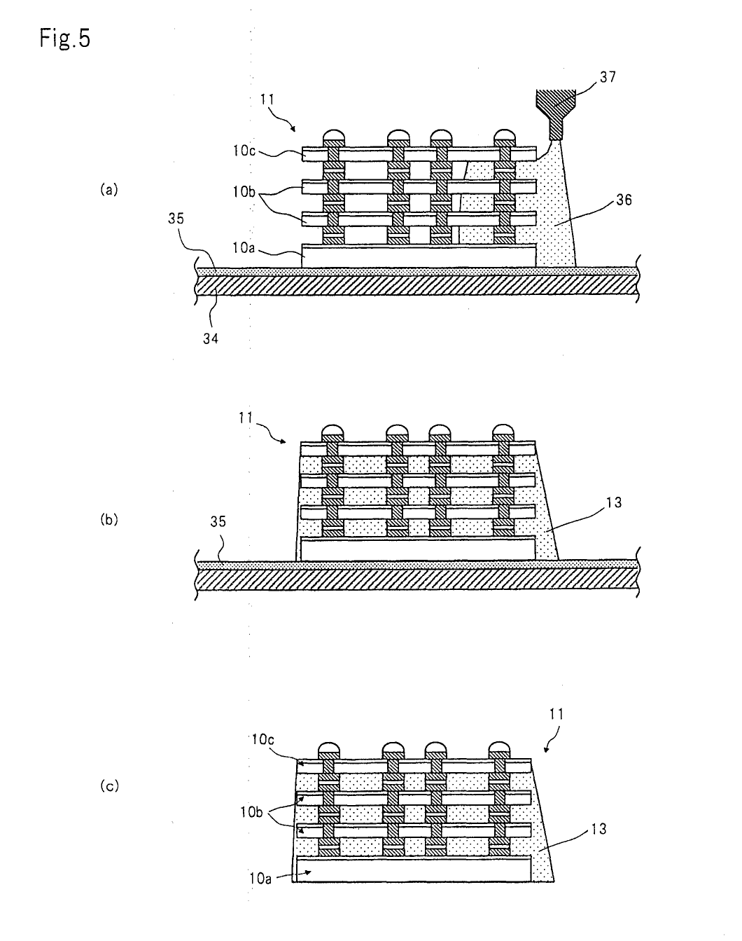

FIG. 4(a) to FIG. 4(d) and FIG. 5(a) to FIG. 5(c) are sectional views showing assembling steps of chip stack 11.

First, as shown in FIG. 4(a), first semiconductor chip 10a (memory chip) is placed on bonding stage 31 so that the rear surface of first semiconductor chip 10a faces bonding stage 31. Thereafter, first semiconductor chip 10a is vacuum-adsorbed by bonding stage 31 so that first semiconductor chip 10a is securely held to bonding stage 31. Since bump electrodes are not formed on the rear surface of first semiconductor chip 10a that is located at the lowermost position of chip stack 11, first semiconductor chip 10a can be satisfactorily held on bonding stage 31.

Secondly, the front surface of second semiconductor chip 10b that is located at the middle position of chip stack 11 is vacuum-adsorbed by bonding tool 32. Thereafter, solder layer 23 of rear bumps 25 on second semiconductor chip 10b that has been vacuum-adsorbed is soaked in a flux bath so as to give flux to the edges of front bumps 22.

Subsequently, as shown in FIG. 4(a), second semiconductor chip 10b where flux has been given to the tips of rear bumps 25 is stacked on first semiconductor chip 10a by the flip-chip bonding method. As a result, rear bumps 25 on second semiconductor chip 10b are respectively connected to the corresponding front bumps 22 on first semiconductor chip 10a through solder layer 23. Solder layer 23 that is melted by heat generated in the flip-chip bonding process spreads between rear bumps 25 on second semiconductor chip 10b and front bumps 22 on first semiconductor chip 10a, and thereby the bumps are satisfactorily connected to each other.

Likewise, the other second semiconductor chip 10b is stacked on second semiconductor chip 10b that has been connected to first semiconductor chip 10a. As a result, rear bumps 25 and the corresponding front bumps 22 between two second semiconductor chips 10b are satisfactorily connected to each other through solder layer 23, and thereby a part of chip stack 11 is manufactured, as shown in FIG. 4(b).

Subsequently, third semiconductor chip 10c that is located at the uppermost position of chip stack 11 is connected to the other second semiconductor chip 10b. In this step, as shown in FIG. 4(c), second bonding stage 33 is prepared where concave parts 33a are formed in locations corresponding to front bumps 22 on third semiconductor chip 10c. Third semiconductor chip 10c is securely held on second bonding stage 33 so that the front surface of third semiconductor chip 10c faces second bonding stage 33 and front bumps 22 are placed in concave parts 33a.

Solder layer 23 is formed on bumps on each surface of third semiconductor chip 10c. Thus, it is preferable that third semiconductor chip 10c is transported by an appropriate transporting unit such as, a suction collet in such a manner that third semiconductor chip 10c is not heated above the melting temperature of solder. Thereby, third semiconductor chip 10c can be transported to second bonding stage 33 without furnishing solder on the bumps to the transporting unit.

Subsequently, a chip stack that is configured by stacking first semiconductor chip 10a and two second semiconductor chips 10b, as described above, is held so that the rear surface of first semiconductor chip 10a is vacuum-adsorbed by bonding tool 32 as shown in FIG. 4(c). And then, front bumps 22 on second semiconductor chip 10b of the adsorbed chip stack are soaked in a flux bath so that flux is furnished to the tips of front bumps 22.

After that, as shown in FIG. 4(d), the chip stack in which flux has been furnished to the tips of front bumps 22 on second semiconductor chip 10b is stacked on third semiconductor chip 10c by the flip-chip bonding method. As a result, rear bumps 25 on third semiconductor chip 10c are respectively connected to the corresponding front bumps 22 on second semiconductor chip 10b of the chip stack through solder layers 23. Solder layer 23 that is melted by heat generated in the flip-chip bonding process spreads between rear bumps 25 on third semiconductor chip 10c and front bumps 22 on second semiconductor chip 10b, and thereby the bumps are satisfactorily connected to each other.

As described above, third semiconductor chip 10c in which solder layer 23 is formed on bumps on each surface is securely held on second bonding stage 33 so that front bumps 22 on third semiconductor chip 10c are placed in concave parts 33a, and then, the chip stack that is composed of first semiconductor chip 10a and second semiconductor chips 10b is connected to the rear surface of third semiconductor chip 10c by the flip-chip bonding method.

In this method, the first to third semiconductor chips can be satisfactorily stacked without crushing solder layer 23 formed on front bumps 22 of third semiconductor chip 10c. Solder layer 23 having a desired thickness can be formed on front bumps 22 of third semiconductor chip 10c that is located at the uppermost position of the chip stack. In addition, because solder layer 23 on the front surface of third semiconductor chip 10c is not crushed, a short-circuit due to a solder bridge between adjacent bumps can be prevented.

Subsequently, as shown in FIG. 5(a), chip stack 11 in which chip stacking process has been finished is placed on coating sheet 35 that is adhered on stage 34. Since coating sheet 35 used a material that is hydrophobic to under-fill material 36, such as a fluorine-based resin sheet or a sheet on which a silicone-based adhesive is coated, under-fill material 36 becomes first sealing resin layer 13.

Under-fill material 36 is supplied by dispenser 37 to the peripheries of chip stack 11 that is placed on coating sheet 35. While under-fill material 36 forms fillets on the peripheries of chip stack 11, under-fill material 36 infiltrates spaces between adjacent semiconductor chips due to the capillary phenomenon. As a result, under-fill material 36 fills the space between first semiconductor chip 10a and second semiconductor chip 10b and the space between second semiconductor chip 10b and third semiconductor chip 10c.

Since coating sheet 35 is composed of a material that is hydrophobic to under-fill material 36, coating sheet 35 prevents under-fill material 36 from excessively spreading and thereby prevents the fillets from excessively widening.

After under-fill material 36 has been formed on chip stack 11, under-fill material 36 is cured at a predetermined temperature, for example, about 150° C. (by thermal treatment). As a result, as shown in FIG. 5(b), first sealing resin layer 13, composed of under-fill material 36 that coats peripheries of chip stack 11 and fills spaces between adjacent semiconductor chips, is formed. According to this embodiment, because coating sheet 35 is composed of a material that is hydrophobic to under-fill material 36, under-fill material 36 is prevented from adhering to coating sheet 35 when under-fill material 36 is cured by thermal treatment.

After first sealing resin layer 13 is heat-cured, as shown in FIG. 5(c), chip stack 11 including first sealing resin layer 13 is removed from coating sheet 35. According to this embodiment, because coating sheet 35 is composed of a material that is hydrophobic to under-fill material 36, chip stack 11 can be easily removed from coating sheet 35.

In addition, since bumps are not formed on the rear surface of first semiconductor chip 10a that is located at the lowermost position of chip stack 11, under-fill material 36 does not infiltrate the rear surface of the semiconductor chip and thereby first sealing resin layer 13 can be satisfactorily formed. Thus, the outer shape of chip stack 11 becomes stable. As a result, when chip stack 11 is connected onto fourth semiconductor chip 10d (for example, a logic chip) of wiring board 12 by the flip-chip bonding method, chip stack 11 can be satisfactorily held and thereby the reliability of flip-chip connections can be improved.

Next, assembling steps of semiconductor device 1 that uses chip stack 11 will be described.

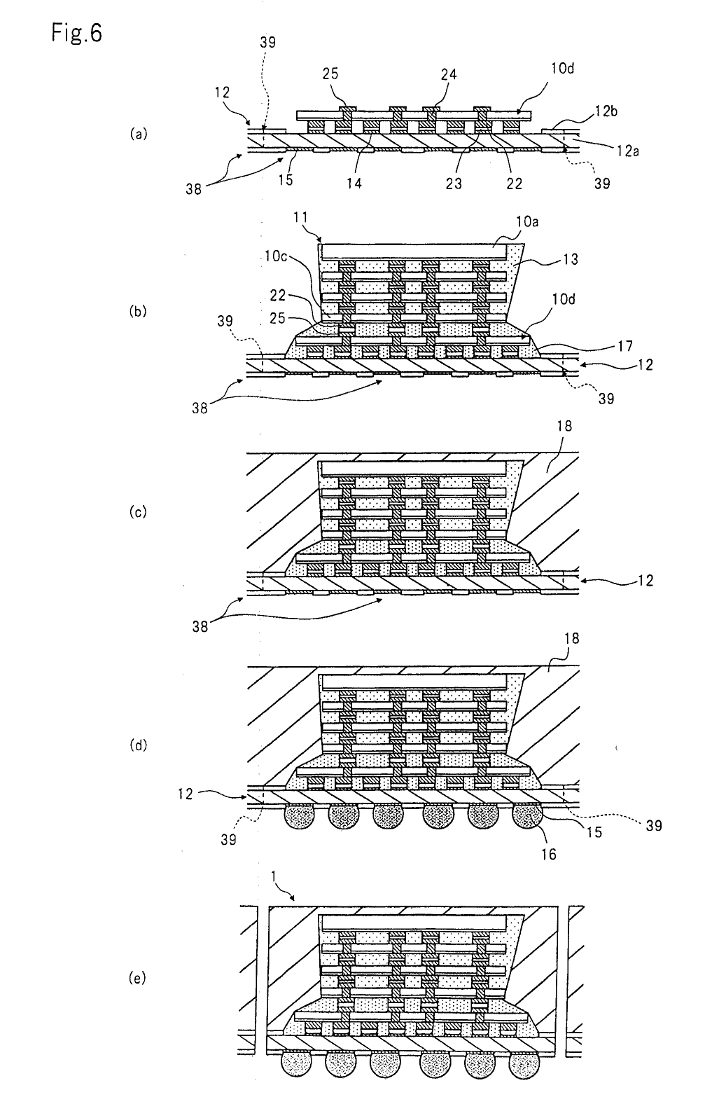

FIG. 6(a) to FIG. 6(e) are sectional views showing the assembling steps of semiconductor device 1 that uses chip stack 11 of this embodiment.

When semiconductor device 1 (refer to FIG. 1) is assembled, wiring board 12 that has a plurality of product forming parts 38, as shown in FIG. 6(a), is prepared first. The plurality of product forming parts 38 are parts in wiring board 12, which are arranged in a matrix shape. Each of product forming parts 38 becomes wiring board 20 in semiconductor device 1.

Each of product forming parts 38 in wiring board 12 is composed of insulation substrate 12a (for example, a glass epoxy substrate) that has wirings (not shown) formed on each surface. Formed on one surface of insulation substrate 12a are a plurality of connection pads 14 to be connected to fourth semiconductor chip 10d. Formed on the other surface of insulation substrate 12a are a plurality of lands 15 to be connected to solder balls 16 that become external terminals. Connection pads 14 are connected to predetermined lands 15 through wirings. Lands 15 are formed on the other surface of wiring board 12 at predetermined intervals, for example, in a grid shape.

Except for connection pads 14 and lands 15, wiring on each surface of insulation substrate 12a is coated with insulation film 12b, such as a solder resist film. The boundaries between adjacent product forming parts 38 in wiring board 20 become dicing lines 39 along which semiconductor devices 1 are separated.

After wiring board 12 has been prepared, as shown in FIG. 6(a), fourth semiconductor chip 10d (logic chip) is mounted on each of product forming parts 38 in wiring board 12. Front bumps 22 on fourth semiconductor chip 10d are connected to connection pads 14 on product forming parts 38 through solder layer 23 by the face-down bonding method. In fourth semiconductor chip 10d (logic chip), a solder layer has not been formed on rear bumps 25 held by a bonding tool (not shown). Front bumps 22 and rear bumps 25 on fourth semiconductor chip 10d are electrically connected through TSVs 24, respectively.

Subsequently, the rear surface of first semiconductor chip 10a of chip stack 11 is adsorbed and held by bonding tool 32 or the like, and then chip stack 11 is mounted and secured on fourth semiconductor chip 10d of each of product forming parts 38 as shown in FIG. 6(b).

According to this embodiment, chip stack 11 is stacked on fourth semiconductor chip 10d by the flip-chip bonding method so that front bumps 22 on third semiconductor chip 10c that is located at the uppermost position are connected to rear bumps 25 on fourth semiconductor chip 10d. Heat that is generated on the flip-chip bonding process causes solder layer 23 on front bumps 22 of third semiconductor chip 10c to melt, and thereby rear bumps 25 on fourth semiconductor chip 10d and front bumps 22 on third semiconductor chip 10c of chip stack 11 are connected.

As a result that chip stack 11 being mounted on fourth semiconductor chip 10d of each of product forming parts 38, first semiconductor chip 10a of chip stack 11 becomes a semiconductor chip that is disposed the farthest apart from wiring board 12.

In chip stack 11 in which a plurality of TSVs 24 are arranged along a straight line and electrically connected in series, temperature changes in the manufacturing process of the chip stack cause the TSVs to expand or shrink, resulting in stress imposed thereon. The highest stress is imposed on the TSVs of the semiconductor chip that is disposed the furthest apart from wiring board 12. Consequently, it is likely that the semiconductor chips have become cracked. However, in this embodiment, first semiconductor chip 10a, in which TSVs and rear side bumps are not formed, having a thickness greater than other semiconductor chip 10b and 10c, is disposed the farthest apart from wiring board 12. Because of this, stress can be imposed on the surface of first semiconductor chip 10a where TSVs and rear bumps are not formed. Consequently, a semiconductor device that prevents occurrence of chip cracks and that has high reliability can be provided.

In addition, after rear bumps 25 on fourth semiconductor chip 10d are connected to front bumps 22 on third semiconductor chip 10c of chip stack 11 by the flip-chip bonding process as mentioned above, an under-fill material is supplied to the peripheries of fourth semiconductor chip 10d that is held on wiring board 12. While the under-fill material forms fillets on the peripheries of fourth semiconductor chip 10d, the under-fill material infiltrates and fills the space between chip stack 11 and fourth semiconductor chip 10d and the space between fourth semiconductor chip 10d and each of product forming parts 38 on wiring board 12 due to the capillary phenomenon.

After the under-fill material has been supplied, the under-fill material is cured at a predetermined temperature, for example, about 150° C. (by thermal treatment). As a result, as shown in FIG. 6(b), second sealing resin layer 17 is formed which is composed of an under-fill material that coats the peripheries of fourth semiconductor chip 10d and that fills the space between third semiconductor chip 10c and fourth semiconductor chip 10d and the space between fourth semiconductor chip 10d and wiring board 12.

Next, wiring board 12 on which fourth semiconductor chip 10d and chip stack 11 have been mounted is set to an upper die and a lower die that comprise a transfer mold unit (not shown). Thereafter, a mold step is performed.

Formed in the upper die is a cavity (not shown) that totally houses the plurality of semiconductor chips 10a to 10d. Fourth semiconductor chip 10d and chip stack 11 that are mounted on wiring board 12 are placed in the cavity.

Thereafter, the heated and melted sealing resin is injected into the cavity of the upper die and then the cavity is filled with the sealing resin so that the sealing resin coats both fourth semiconductor chip 10d and chip stack 11. The sealing resin is a thermosetting resin, such as an epoxy resin.

After the cavity was filled with the sealing resin, the sealing resin is heat-cured at a predetermined temperature, for example, about 180° C. As a result, as shown in FIG. 6(c), third sealing resin layer 18 that coats both fourth semiconductor chip 10d and chip stack 11 that are mounted on each of product forming parts 38, is formed. In addition, the sealing resin (third sealing resin layer 18) is baked at a predetermined temperature so as to completely cure it.

According to this embodiment, each space of semiconductor chips 10a to 10d is filled with first sealing resin layer 13 and second sealing resin layer 17 (under-fill materials), and then, third sealing resin layer 18 is formed that entirely coats the chip stack composed of semiconductor chips 10a to 10d. Thus, the occurrence of voids between adjacent semiconductor chips can be prevented.

After third sealing resin layer 18 is formed, a ball mount step is performed. As shown in FIG. 6(d), electro-conductive metal balls, for example, solder balls 16, which become external terminals of the semiconductor devices are connected to lands 15 that are formed on the other surface of wiring board 12.

In the ball mount step, the plurality of solder balls 16 are absorbed and held using a mount tool (not shown) that has a plurality of adsorption holes corresponding to lands 15 of wiring board 12. After flux is given to solder balls 16, all solder balls 16 held by the mounting tool are mounted together on lands 15 of wiring board 12.

After solder balls 16 have been mounted on all product forming parts 38, wiring board 12 is passed through a reflow oven so as to connect solder balls 16 and lands 15.

After solder balls 16 and lands 15 have been connected, a wiring board dicing step is performed. As shown in FIG. 6(d), product forming parts 38 are cut and separated along predetermined dicing lines 39 so as to form CoC type semiconductor devices 1.

Next, semiconductor device 1 according to a modification of the foregoing embodiment will be described.

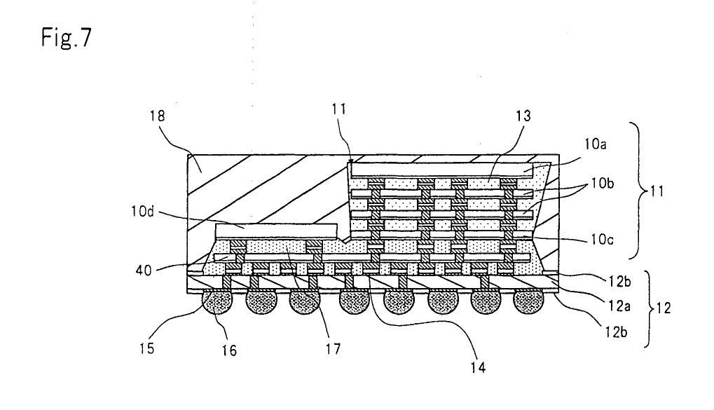

FIG. 7 is a sectional view showing a semiconductor device using a chip stack according to a modification of the foregoing embodiment. In FIG. 7, similar parts to those shown in FIG. 1 are denoted by similar reference numerals.

In the semiconductor device shown in FIG. 7, chip stack 11, which is composed of a plurality of memory chips (first to third semiconductor chips 10a to 10c), is stacked on interposer chip 40 that is mounted on wiring board 12.

In addition, a logic chip (fourth semiconductor chip 10d) is stacked on interposer chip 40 such that the location of the logic chip is different from that of chip stack 11. Chip stack 11 and fourth semiconductor chip 10d are disposed side by side on interposer chip 40. Chip stack 11 and fourth semiconductor chip 10d are electrically connected through wirings (not shown) that are formed on interposer chip 40.

Interposer chip 40 is a chip using a silicon board on which no circuit is formed. However, in interposer chip 40, electrodes are formed on each surface of a silicon board. Electrodes on the front surface of the silicon board are electrically connected to the corresponding electrodes on the rear surface of the silicon board through wirings formed on the silicon board and vias that pierce the silicon board.

As with this modification, even if a semiconductor chip on which chip stack 11 of the present invention is mounted is not an interposer chip but is a logic chip, the semiconductor chip that is an interposer chip has the same effects as the semiconductor chip that is a logic chip. Also, if front bumps 22 on third semiconductor chip 10c of semiconductor device 1 are formed at narrow pitches, chip stack 11 is preferably stacked on wiring board 12 through interposer chip 40. Thereby, connections between a plurality of bump electrodes of chip stack 11 and connection pads 14 of wiring board 12 can be changed corresponding to the locations of connection pads 14.

In the foregoing embodiment, semiconductor chips are stacked, and then spaces between adjacent semiconductor chips are filled with the under-fill materials. Alternatively, before semiconductor chips are stacked, a resin material, such as NCF (Non Conductive Film, insulation resin adhesive film) or NCP (Non Conductive Paste), may be formed on chips, and then the semiconductor chips may be stacked by the flip-chip bonding method.

### Second Embodiment

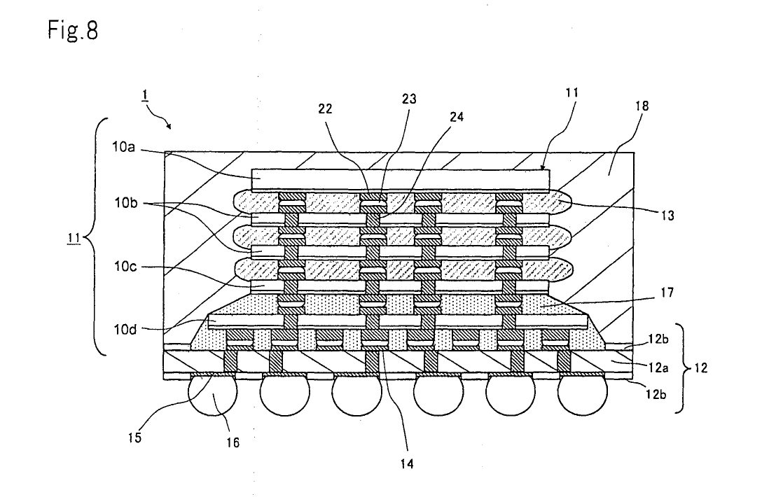

FIG. 8 is a sectional view showing an outline of the structure of a CoC type semiconductor device according to a second embodiment of the present invention.

In the second embodiment, like the foregoing first embodiment, chip stack 11 that is composed of a plurality of memory chips (first to third semiconductor chips 10a to 10c) is mounted on a logic chip (fourth semiconductor chip 10d) that has been mounted on wiring board 12. A memory circuit and a plurality of bump electrodes are formed on one surface of each of the memory chips. The structures of the memory circuits of the memory chips are substantially the same. The locations of the bump electrodes formed on one surface of each of the memory chips are substantially the same. In addition, the memory chips (semiconductor chips 10a to 10c) that comprise chip stack 11 are three types of memory chips that have substantially the same memory circuits but slightly different structures and that perform substantially the same operations.

The second embodiment is different from the foregoing first embodiment in that an NCF (Non Conductive Film) is formed in spaces of adjacent semiconductor chips of chip stack 11 as shown in FIG. 8. In other words, first sealing resin layer 13 that fills spaces between adjacent chips of semiconductor chips 10a to 10c is made of an NCF instead of an under-fill material. Thus, as is clear from a comparison of FIG. 8 and FIG. 1, the cross-section of first sealing resin layer 13 viewed from the side of chip stack 11 is different from that of the first embodiment.

The second embodiment has the same effects as the first embodiment. Unlike the first embodiment, in the second embodiment, since spaces of adjacent semiconductor chips are filled with the NCF, fillets of the under-fill material are not formed on the peripheries of chip stack 11. As a result, since spaces of adjacent semiconductor chips can be evenly filled with the resin material, stress that is caused by hardening shrinkage of the resin material can be reduced and thereby the reliability of the semiconductor devices can be improved.

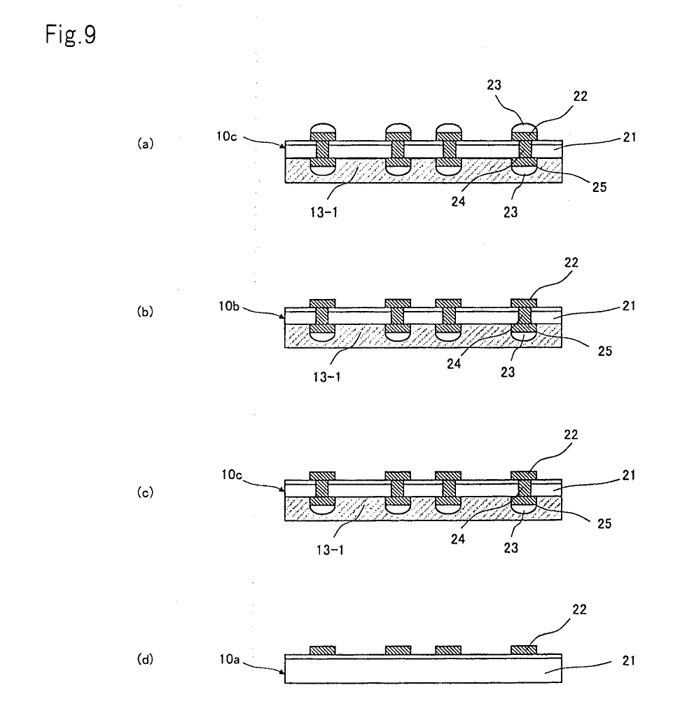

FIG. 9(a) to FIG. 9(d) are sectional views showing an outline of the structures of a plurality of semiconductor chips 10a to 10c that comprise chip stack 11 according to the second embodiment.

The structures of first to third semiconductor chips 10a to 10c of this embodiment are the same as those of the first embodiment. However, in the second embodiment, the format NCF layer 13-1 is formed on the rear surface of each of second and third semiconductor chips 10b and 10c, and rear bumps 25 on each of second and third semiconductor chips 10b and 10c are coated with NCF layer 13-1.

The NCF of the second embodiment and the under-fill materials of the first embodiment are made of an epoxy resin. Since the under-fill materials are used to fill spaces of adjacent semiconductor chips after the flip-chip bonding process is performed, the under-fill materials contains a liquefying solvent. In contrast, the NCF is a film-shaped resin and contains a flux activation material that allows bump electrodes to be satisfactorily connected when the flip-chip bonding process is performed. The flux activation material is, for example, an organic acid or an amine.

Next, assembling steps of chip stack 11 according to the second embodiment will be described.

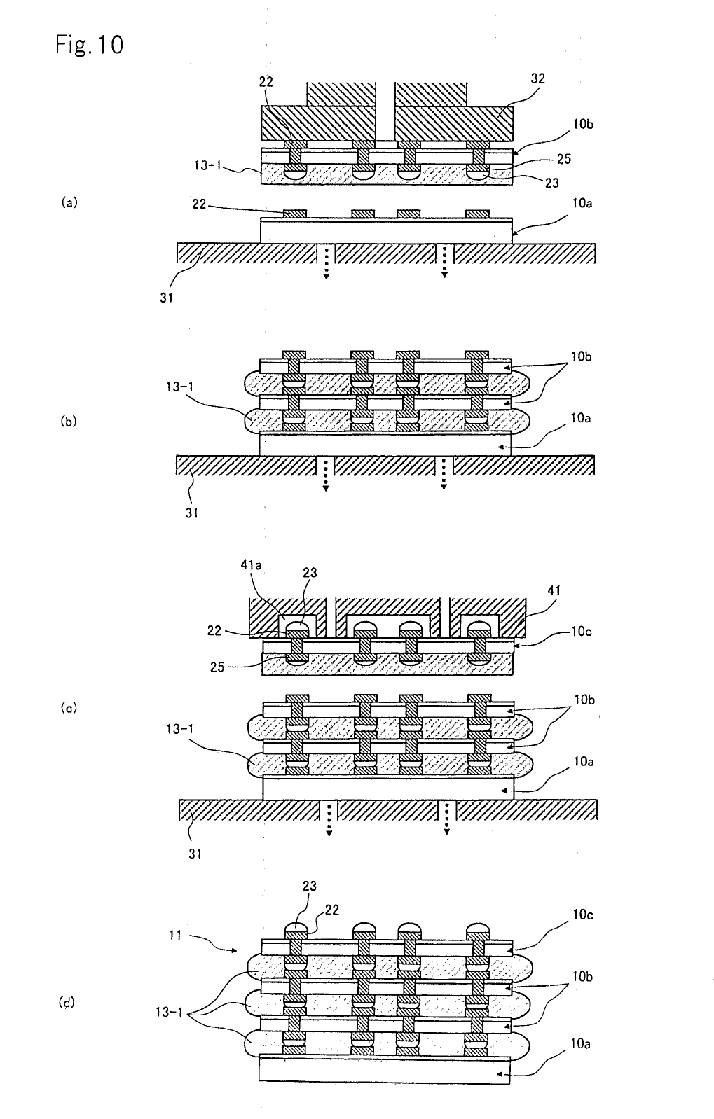

FIG. 10(a) to FIG. 10(d) are sectional views showing the assembling steps of chip stack 11 according to the second embodiment.

First, as shown in FIG. 10(a), first semiconductor chip 10a (memory chip) is placed on bonding stage 31 so that the rear surface of first semiconductor chip 10a faces bonding stage 31. And then, first semiconductor chip 10a is vacuum-adsorbed by bonding stage 31 to securely hold first semiconductor chip 10a on bonding stage 31. Since bump electrodes are not formed on the rear surface of first semiconductor chip 10a that is located at the lowermost position of chip stack 11, first semiconductor chip 10a can be satisfactorily held on bonding stage 31.

Subsequently, the front surface of second semiconductor chip 10b that is located at the middle position of chip stack 11 is vacuum-adsorbed by bonding tool 32. Solder layer 23 has been formed on rear bumps 25 of second semiconductor chip 10b. In addition, all rear bumps 25 have been coated with NCF layer 13-1.

Thereafter, second semiconductor chip 10b in which NCF layer 13-1 has been provided is pressed to first semiconductor chip 10a through NCF layer 13-1 by means of bonding tool 32 so that rear bumps 25 on second semiconductor chip 10b and front bumps 22 on first semiconductor chip 10a are bonded by the thermal compression. As a result, the melted NCF layer 13-1 seals a space between first semiconductor chip 10a and second semiconductor chip 10b.

Unlike the first embodiment (refer to FIG. 5(a) to FIG. 5(c)), this method does not need a step that forms an under-fill resin that seals the spaces of adjacent semiconductor chips of chip stack 11. As a result, the manufacturing process of the semiconductor devices can be simplified. In addition, since NCF layer 13-1 contains a flux activation material, after the NCF layer is formed on first semiconductor chip 10a, even if second semiconductor chip 10b is stacked on first semiconductor chip 10a by using the flip-chip bonding method, rear bumps 25 on second semiconductor chip 10b can be satisfactorily connected to front bumps 22 on first semiconductor chip 10a.

Another second semiconductor chip 10b on which NCF layer 13-1 has been formed is connected to the foregoing chip stack by the connecting method as mentioned above. As a result, a part of chip stack 11 is manufactured (FIG. 10(b)). Likewise, third semiconductor chip 10c on which NCF layer 13-1 has been formed is connected to the other second semiconductor chip 10b. As a result, chip stack 11 is manufactured (FIG. 10(d)). In the case in which the under-fill materials is replaced with the NCF, the amount of insulation resin that coats chip stack 11 can be decreased compared with the first embodiment. Thereby, stress that is imposed on chip stack 11 by hardening shrinkage of the insulation resin can be reduced.

Furthermore, solder layer 23 has been formed on front bumps 22 of third semiconductor chip 10c that is located at the uppermost position of chip stack 11. Because of this, as to a means that adsorbs and holds the front surface of third semiconductor chip 10c, second bonding tool 41 is used, in which concave parts 41a are formed at locations corresponding to front bumps 22 on third semiconductor chip 10c as shown in FIG. 10(c).

Therefore, second bonding tool 41 allows third semiconductor chip 10c to be satisfactorily stacked without crushing solder layer 23 that is formed on front bumps 22 of third semiconductor-chip 10c. Solder layer 23 that has the desired thickness can be formed on front bumps 22 of third semiconductor chip 10c that is located at the uppermost position. In addition, because solder layer 23 on the front surface of third semiconductor chip 10c is not crushed, a short-circuit, that is caused by a solder bridge that occurs between adjacent bumps, can be prevented.

In the first embodiment, after the chip stack is manufactured, it may be necessary to use a robot hand to carry a chip stack from bonding stage 31 to an equipment that fills the chip stack with the under-fill materials (refer to FIG. 5). In this case, it will be likely that such handling will cause a risk in which stress is imposed on the chip stack. However, the second embodiment can reduce such a risk. Also, since the first embodiment has used the capillary phenomenon to fill the spaces between adjacent semiconductor chips with the under-fill materials, the filling process takes a relatively long time. In contrast, in the second embodiment, as soon as chips are stacked, spaces of adjacent semiconductor chips are filled with the NCF. As a result, in the second embodiment, the assembling cost of the semiconductor device can be reduced.

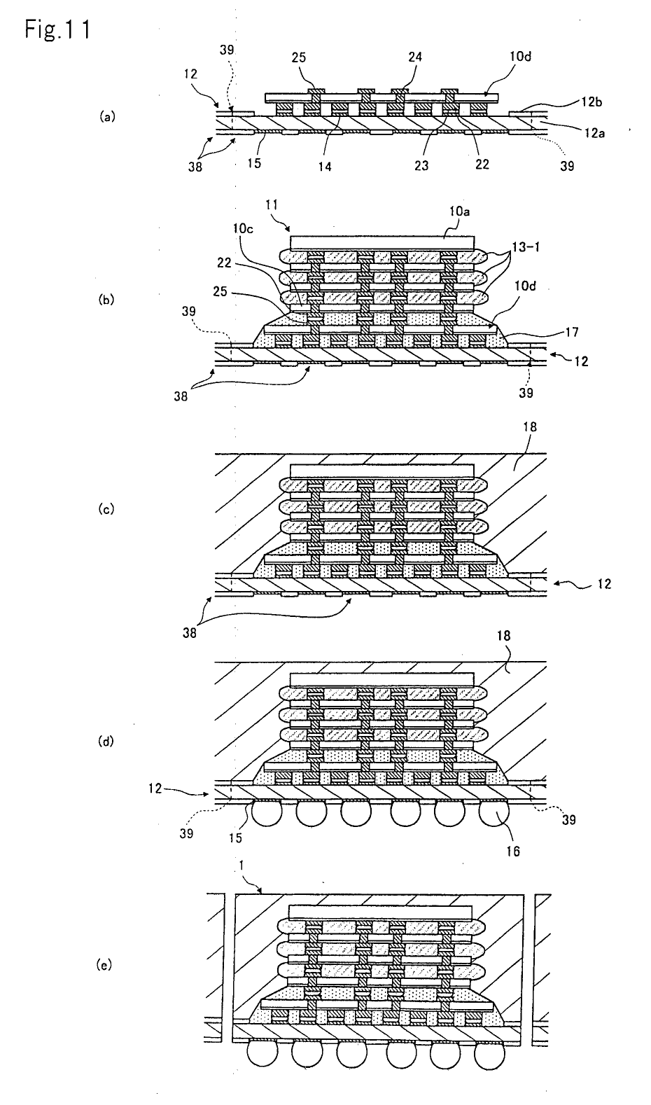

FIG. 11(a) to FIG. 11(e) are sectional views showing assembling steps of the semiconductor device according to the second embodiment. The assembling steps of semiconductor device 1 using chip stack 11 according to the second embodiment are the same as the first embodiment (refer to FIG. 6(a) to FIG. 6(e)) as shown in FIG. 11(a) to FIG. 11(e). In addition, the modification shown in FIG. 7 can be applied to semiconductor device 1 according to the second embodiment.

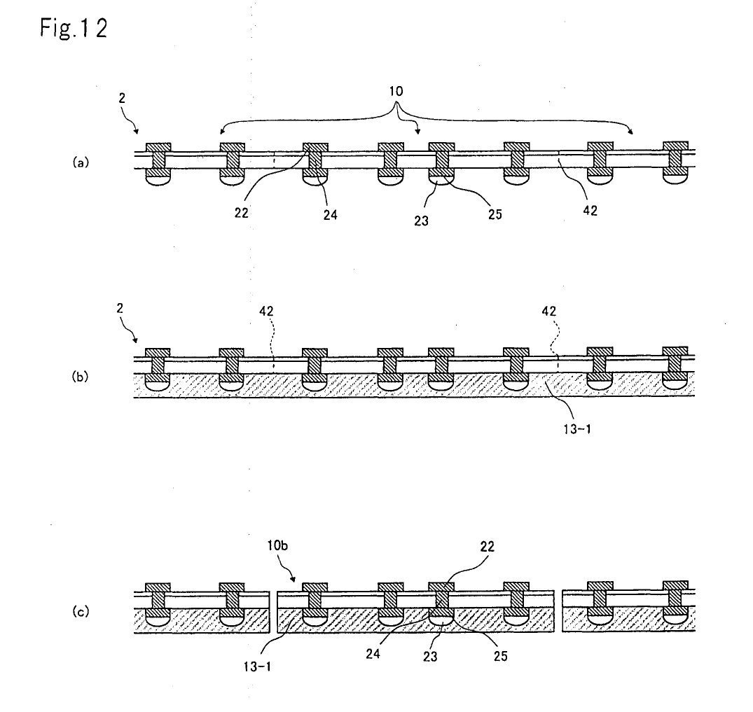

FIG. 12(a) to FIG. 12(c) are sectional views showing the assembling steps of semiconductor chips in which the NCF layer is formed. When the chip stack according to the second embodiment is assembled, semiconductor chips are prepared in which NCF layer 13-1 (10b and 10c) has been formed on their rear surface.

Specifically, first, semiconductor wafer 2 as shown in FIG. 12(a) is prepared. With respect to this semiconductor wafer 2, predetermined front bumps 22 are formed on one surface thereof, whereas rear bumps 25 are formed on the other surface thereof. A plurality of semiconductor chips 10, in which front bumps 22 and rear bumps 25 are connected through TSVs 24, are disposed. Semiconductor chips 10 are partitioned along dicing lines 42.

Next, as shown in FIG. 12(b), NCF layer 13-1 is formed on the entire rear surface of semiconductor wafer 2.

Thereafter, as shown in FIG. 12(c), semiconductor wafer 2 is cut along dicing lines 42 into each semiconductor chip 10 (in this example, second semiconductor chip 10b). At the same time that semiconductor wafer 2 is cut, NCF layer 13-1 is also cut. As a result, semiconductor chips, in which NCF layer 13-1 has been formed on their rear surface, can be obtained.

Since semiconductor chips having the NCF layer as mentioned above are prepared, the strength of semiconductor chips that have a thickness, such as 50 μm can be improved.

The present invention has been described with reference to the embodiments. However, the present invention is not limited to the foregoing embodiments, it should be understood by any person skilled in the art that the structure and details of the present invention may be changed in various manners without departing from the scope of the present invention.

In the foregoing embodiments, a solder layer is formed on bump electrodes of a chip stack that is composed of memory chips of the same type. Alternatively, a solder layer may be formed on bump electrodes of a chip stack that is composed of a plurality of semiconductor chips of different types.

In the foregoing embodiments, a chip stack that is composed of four semiconductor chips was described. The present invention can be applied to a chip stack that is composed of three semiconductor chips or five or more semiconductor chips, so long as a solder layer is formed on bump electrodes on the rear surface of a semiconductor chip that is located at the uppermost position of the chip stack.

Although the inventions has been described above in connection with several preferred embodiments thereof, it will be appreciated by those skilled in the art that those embodiments are provided solely for illustrating the invention, and should not be relied upon to construe the appended claims in a limiting sense.

Furthermore, this application includes inventions of subject mattes 1 to 15 as described below.

### [Subject Matter 1]

A chip stack that is configured by stacking a plurality of semiconductor chips, in which a plurality of bump electrodes are formed at the same locations in the respective semiconductor chips, said chip stack comprising:

a first semiconductor chip that has a plurality of first bump electrodes formed only on a first surface thereof;

a second semiconductor chip that comprises: a plurality of second bump electrodes formed on a first surface thereof; and a plurality of third bump electrodes that are formed on a second surface thereof and that are electrically connected to said plurality of second bump electrodes, respectively, wherein said second semiconductor chip is stacked on said first semiconductor chip, said plurality of third bump electrodes are electrically connected to said plurality of first bump electrodes through a first solder layer, respectively; and

a third semiconductor chip that comprises: a plurality of fourth bump electrodes formed on a first surface thereof; second solder layers respectively formed on said plurality of fourth bump electrodes; and a plurality of fifth bump electrodes that are formed on a second surface thereof and that are electrically connected to said plurality of fourth bump electrodes, respectively, wherein said third semiconductor chip is stacked on said second semiconductor chip, said plurality of fifth bump electrodes are electrically connected to said plurality of second bump electrodes through a third solder layer, respectively.

### [Subject Matter 2]

The chip stack as set forth in Subject matter 1, wherein

said second semiconductor chip has first through-electrodes that connect said second bump electrodes and said third bump electrodes to each other,

said third semiconductor chip has second through-electrodes that connect said fourth bump electrodes and said fifth bump electrodes to each other, and

said first through-electrodes and said second through-electrodes are arranged in a straight line and are connected in series.

### [Subject Matter 3]

The chip stack as set forth in Subject matter 2, wherein

the thickness of said first semiconductor chip is greater than that of each of said second semiconductor chip and said third semiconductor chip.

### [Subject Matter 4]

The chip stack as set forth in Subject matter 1, further comprising:

a sealing resin layer that is composed of a resin that fills at least a space between said first semiconductor chip and said second semiconductor chip and a space between said second semiconductor chip and said third semiconductor chip.

### [Subject Matter 5]

A semiconductor device, comprising:

a chip stack as set forth in Subject matter 1;

a fourth semiconductor chip; and

a wiring board that has a first surface on which said fourth semiconductor chip is mounted, wherein said chip stack is stacked on said fourth semiconductor chip,

wherein a plurality of sixth bump electrodes are formed on a surface opposite to said wiring board of said fourth semiconductor chip, and

said plurality of fourth bump electrodes on said third semiconductor chip are electrically connected to part or all of said plurality of sixth bump electrodes through said second solder layer, respectively.

### [Subject Matter 6]

The semiconductor device as set forth in Subject matter 5, further comprising:

a second sealing resin layer that is composed of a resin that fills at least a space between said third semiconductor chip and said fourth semiconductor chip and a space between said fourth semiconductor chip and said wiring board; and

a third sealing resin layer that coats and seals both said chip stack stacked on said wiring board and said fourth semiconductor chip.

### [Subject Matter 7]

A manufacturing method for a semiconductor device that comprises: a chip stack that is configured by stacking at least a first semiconductor chip, a second semiconductor chip, and a third semiconductor chip, in which a plurality of bump electrodes are formed at the same locations in the respective semiconductor chips; a fourth semiconductor chip; and a wiring board that has a first surface on which said fourth semiconductor chip is mounted, wherein said chip stack is stacked on said fourth semiconductor chip, comprising:

preparing a first semiconductor chip that has a plurality of first bump electrodes formed only on a first surface thereof;

preparing a second semiconductor that comprises a plurality of second bump electrodes formed on a first surface thereof; a plurality of third bump electrodes that are formed on a second surface thereof and that are electrically connected to said plurality of second bump electrodes, respectively; and first solder layers respectively formed on said plurality of third bump electrodes, wherein said second bump electrodes and said third bump electrodes are respectively formed corresponding to the locations of said first bump electrodes;

preparing a third semiconductor chip that comprises a plurality of fourth bump electrodes formed on a first surface thereof; second solder layers respectively formed on said plurality of fourth bump electrodes; a plurality of fifth bump electrodes that are formed on a second surface thereof and that are electrically connected to said plurality of fourth bump electrodes, respectively; and third solder layers respectively formed on said plurality of fifth bump electrodes, wherein said fourth bump electrodes and said fifth bump electrodes are respectively formed corresponding to the locations of said plurality of first bump electrodes;

preparing a fourth semiconductor chip that comprises a plurality of sixth bump electrodes formed on a first surface thereof; and a plurality of seventh bump electrodes that are formed on a second surface thereof and that are electrically connected to said plurality of sixth bump electrodes, respectively;

preparing a wiring board that can connect said plurality of sixth bump electrodes of said fourth semiconductor chip on a first surface thereof;

placing said first semiconductor chip on a flat stage such that said first surface of said first semiconductor chip faces upward;

stacking said second semiconductor chip on said first semiconductor chip so that said plurality of third bump electrodes are electrically connected to said plurality of first bump electrodes through said first solder layer, respectively;

stacking said third semiconductor chip on said second semiconductor chip so that said plurality of fifth bump electrodes are electrically connected to said plurality of second bump electrodes through said third solder layer, respectively;

placing said chip stack, that is configured by stacking said first semiconductor chip, said second semiconductor chip, and said third semiconductor chip, on a flat second stage, so that said first surface of said third semiconductor chip faces upward, and then filling a space between said first semiconductor chip and said second semiconductor chip and a space between said second semiconductor chip and said third semiconductor chip with an under-fill material;

mounting said fourth semiconductor chip on said wiring board so that said plurality of sixth bump electrodes are electrically connected to said wiring board; and

stacking said chip stack, in which under-fill material has been provided, on said fourth semiconductor chip mounted on said wiring board, so that said plurality of fourth bump electrodes are electrically connected to part or all of said plurality of seventh bump electrodes through said second solder layer, respectively.

### [Subject Matter 8]

The manufacturing method for the semiconductor device as set forth in Subject matter 7, wherein a step of stacking said third semiconductor chip on said second semiconductor chip comprises:

placing said third semiconductor chip on a third stage which has a plurality of concave parts that are formed on a first surface thereof and that can hold said plurality of fourth bump electrodes of said third semiconductor chip in state in which said fourth bump electrodes on which said second solder layer is formed are held in the concave parts; and

stacking a stack, that is configured by stacking said first semiconductor chip and said second semiconductor chip, on said third semiconductor chip that is placed on said third stage, so that said plurality of second bump electrodes are electrically connected to said plurality of fifth bump electrodes through said third solder layer, respectively.

### [Subject Matter 9]

The manufacturing method for the semiconductor device as set forth in Subject matter 7, further comprising:

after said chip stack is stacked on said fourth semiconductor chip mounted on said wiring board, filling a space between said third semiconductor chip and said fourth semiconductor chip and a space between said fourth semiconductor chip and said wiring board with an under-fill material.

[Subject matter 10]

The manufacturing method for the semiconductor device as set forth in Subject matter 7, wherein

the thickness of said second solder layer formed on said fourth bump electrodes is greater than that of said third solder layer formed on said fifth bump electrodes.

### [Subject Matter 11]

The manufacturing method for the semiconductor device as set forth in Subject matter 7, wherein

bump electrodes between said first semiconductor chip and said second semiconductor chip, bump electrodes between said second semiconductor chip and said third semiconductor chip, bump electrodes between said third semiconductor chip and said fourth semiconductor chip, and bump electrodes between said fourth semiconductor chip and said wiring board are respectively connected with each solder layer that is melted.

### [Subject Matter 12]

A manufacturing method for a semiconductor device that comprises: a chip stack that is configured by stacking at least a first semiconductor chip, a second semiconductor chip, and a third semiconductor chip, in which a plurality of bump electrodes are formed at the same locations in the respective semiconductor chips; a fourth semiconductor chip; and a wiring board that has a first surface on which said fourth semiconductor chip is mounted, wherein said chip stack is stacked on said fourth semiconductor chip, comprising:

preparing a first semiconductor chip that has a plurality of first bump electrodes formed only on a first surface thereof;

preparing a second semiconductor that comprises a plurality of second bump electrodes formed on a first surface thereof; a plurality of third bump electrodes that are formed on a second surface thereof and that are electrically connected to said plurality of second bump electrodes, respectively; first solder layers respectively formed on said plurality of third bump electrodes; and a first insulation resin adhesive film (NCF) that coats said plurality of third bump electrodes formed on said second surface thereof, wherein said second bump electrodes and said third bump electrodes are respectively formed corresponding to the locations of said first bump electrodes;

preparing a third semiconductor chip that comprises a plurality of fourth bump electrodes formed on a first surface thereof; second solder layers respectively formed on said plurality of fourth bump electrodes; a plurality of fifth bump electrodes that are formed on a second surface thereof and that are electrically connected to said plurality of fourth bump electrodes, respectively; third solder layers respectively formed on said plurality of fifth bump electrodes; and a second insulation resin adhesive film (NCF) that coats said plurality of fifth bump electrodes formed on said second surface thereof, wherein said fourth bump electrodes and said fifth bump electrodes are respectively formed corresponding to the locations of said plurality of first bump electrodes;

preparing a fourth semiconductor chip that comprises a plurality of sixth bump electrodes formed on a first surface thereof; and a plurality of seventh bump electrodes that are formed on a second surface thereof and that are electrically connected to said plurality of sixth bump electrodes, respectively;

preparing a wiring board that can connect said plurality of sixth bump electrodes of said fourth semiconductor chip on a first surface thereof;

placing said first semiconductor chip on a flat stage such that said first surface of said first semiconductor chip faces upward;

stacking said second semiconductor chip on said first semiconductor chip so that said plurality of third bump electrodes are electrically connected to said plurality of first bump electrodes through said first solder layer, respectively, and then filling a space between said first semiconductor chip and said second semiconductor chip with said first insulation resin adhesive film;

stacking said third semiconductor chip on said second semiconductor chip so that said plurality of fifth bump electrodes are electrically connected to said plurality of second bump electrodes through said third solder layer, respectively, and then filling a space between said second semiconductor chip and said third semiconductor chip with said second insulation resin adhesive film;

mounting said fourth semiconductor chip on said wiring board so that said plurality of sixth bump electrodes are electrically connected to said wiring board; and

stacking said chip stack, that is configured by stacking said first semiconductor chip, said second semiconductor chip, and said third semiconductor chip, on said fourth semiconductor chip mounted on said wiring board, so that said plurality of fourth bump electrodes are electrically connected to part or all of said plurality of seventh bump electrodes through said second solder layer, respectively.

### [Subject Matter 13]

The manufacturing method for the semiconductor device as set forth in Subject matter 12, further comprising:

preparing a bonding tool that adsorbs said first surface of said third semiconductor chip and that has a plurality of concave parts that can house said plurality of fourth bump electrodes on which said second solder layer is formed;

wherein in a step of stacking said third semiconductor chip on said second semiconductor chip, said bonding tool houses said fourth bump electrodes in said concave parts thereof.

### [Subject Matter 14]

The manufacturing method for the semiconductor device as set forth in Subject matter 12, further comprising:

after said chip stack is stacked on said fourth semiconductor chip mounted on said wiring board, filling a space between said third semiconductor chip and said fourth semiconductor chip and a space between said fourth semiconductor chip and said wiring board with an under-fill material.

### [Subject Matter 15]

The manufacturing method for the semiconductor device as set forth in Subject matter 12,

wherein the thickness of said second solder layer formed on said fourth bump electrodes is greater than that of said third solder layer formed on said fifth bump electrodes.

### [Subject Matter 16]

The manufacturing method for the semiconductor device as set forth in Subject matter 12, wherein

bump electrodes between said first semiconductor chip and said second semiconductor chip, bump electrodes between said second semiconductor chip and said third semiconductor chip, bump electrodes between said third semiconductor chip and said fourth semiconductor chip, and bump electrodes between said fourth semiconductor chip and said wiring board are respectively connected with each solder layer that is melted.

1. A manufacturing method for a semiconductor device, comprising:
preparing a first semiconductor chip that has a plurality of first bump electrodes formed on a first surface thereof;
preparing a second semiconductor that comprises a plurality of second bump electrodes formed on a first surface thereof, a plurality of third bump electrodes that are formed on a second surface thereof and that are electrically connected to said plurality of second bump electrodes, respectively, and first solder layers respectively formed on said plurality of third bump electrodes;
preparing a third semiconductor chip that comprises a plurality of fourth bump electrodes formed on a first surface thereof, second solder layers respectively formed on said plurality of fourth bump electrodes, a plurality of fifth bump electrodes that are formed on a second surface thereof and that are electrically connected to said plurality of fourth bump electrodes, respectively, and third solder layers respectively formed on said plurality of fifth bump electrodes;
preparing a fourth semiconductor chip that comprises a plurality of sixth bump electrodes formed on a first surface thereof, and a plurality of seventh bump electrodes that are formed on a second surface thereof and that are electrically connected to said plurality of sixth bump electrodes, respectively;
preparing a wiring board that comprises a plurality of connection pads formed on a first surface thereof;
stacking said second semiconductor chip on said first semiconductor chip so that said plurality of third bump electrodes are electrically connected to said plurality of first bump electrodes through said first solder layer, respectively;
stacking said third semiconductor chip over said second semiconductor chip so that said plurality of fifth bump electrodes are electrically connected to said plurality of second bump electrodes through said third solder layer, respectively;
mounting said fourth semiconductor chip on said wiring board so that said plurality of sixth bump electrodes are electrically connected to said connection pads of said wiring board; and
stacking a chip stack, that is configured by stacking said first semiconductor chip, said second semiconductor chip, and said third semiconductor chip, on said fourth semiconductor chip mounted on said wiring board, so that said plurality of fourth bump electrodes are electrically connected to part or all of said plurality of seventh bump electrodes through said second solder layer, respectively.

2. The manufacturing method for the semiconductor device as set forth in claim 1, wherein
the thickness of said second solder layer formed on said fourth bump electrodes is greater than that of said third solder layer formed on said fifth bump electrodes.

3. The manufacturing method for the semiconductor device as set forth in claim 1, wherein the first semiconductor chip comprises a first circuit configuration on a side of the first surface,
the second semiconductor chip comprises a second circuit configuration on a side of the first surface,
the third memory chip comprises a third circuit configuration on a side of the first surface, and
the first, second third circuit configurations are substantially identical.

4. The manufacturing method for the semiconductor device as set forth in claim 3, wherein first memory chip is larger in thickness than each of the second and third memory chips.

5. The manufacturing method for the semiconductor device as set forth in claim 4, wherein the second semiconductor chip includes a plurality of first through electrodes, the third bump electrodes are electrically connected to the second bump electrodes via the first through electrodes, respectively, and
the third semiconductor chip includes a plurality of second through electrodes, the fifth bump electrodes are electrically connected to the fourth bump electrodes via the second through electrodes, respectively.

6. The manufacturing method for the semiconductor device as set forth in claim 5, wherein the first semiconductor chip is larger in thickness than each of the second and third semiconductor chips.

7. The manufacturing method for the semiconductor device as set forth in claim 6, further comprising:
after the step of stacking the third semiconductor chip over the second semiconductor chip, supplying an under-fill material in the chip stack, a first gap between the first and second semiconductor chips and a second gap between the second and third semiconductor chips are filled by the under-fill material at the same time.

8. The manufacturing method for the semiconductor device as set forth in claim 6, wherein the second semiconductor chip includes a first insulation resin film on the third surface, a gap between the first and second semiconductor chips is filled by the first insulation resin film, by the step of stacking the second semiconductor chip on the first semiconductor chip, and
the third semiconductor chip includes a second insulation resin film on the fifth surface, a gap between the second and third semiconductor chips is filled by the second insulation resin film, by the step of stacking the third semiconductor chip over the second semiconductor chip.

9. The manufacturing method for the semiconductor device as set forth in claim 6, wherein each of the first, second and third semiconductor chips is a memory chip, and
the fourth semiconductor chip is logic chip.

10. The manufacturing method for the semiconductor device as set forth in claim 6, wherein each of the first, second and third semiconductor chips is a memory chip, and the fourth semiconductor chip is interposer chip.

11. A method comprising:
preparing a first memory chip including a plurality of first bump electrodes formed on a first surface thereof;
preparing a second memory chip including a plurality of second bump electrodes formed on a second surface thereof, a plurality of third bump electrodes formed on a third surface thereof and a plurality of first solder layers respectively formed on the plurality of third bump electrodes;
preparing a third memory chip including a plurality of fourth bump electrodes formed on a fourth surface thereof, a plurality of second solder layers respectively formed on the plurality of fourth bump electrodes, a plurality of fifth bump electrodes formed on a fifth surface thereof and a plurality of third solder layers respectively formed on the fifth bump electrodes;
stacking the second memory chip over the first memory chip so that the third bump electrodes electrically couple to the first bump electrodes of the first memory chip via the first solder layers; and
after the step of stacking the second memory chip over the first memory chip, stacking the third memory chip over the second memory chip so that the fifth bump electrodes electrically couple to the third bump electrodes of the second memory chip via the third solder layers, to form a chip stack that is constructed by the first, second and third memory chips.

12. The method as claimed in claim 11, further comprising:
preparing a logic chip including a plurality of sixth bump electrodes on a sixth surface thereof and a plurality of seventh bump electrodes on a seventh surface thereof;
preparing a wiring substrate including a plurality of connection pads thereon;
mounting the logic chip over the wiring substrate so that the seventh bump electrodes electrically couple to the connection pads of the wiring substrate; and
after the step of stacking the third memory chip over the second memory chip, stacking the chip stack over the logic chip so that the fourth bump electrodes electrically couple to the sixth bump electrodes of the logic chip via the second solder layers.

13. The method as claimed in claim 11, further comprising:
preparing a interposer chip including a plurality of sixth bump electrodes on a sixth surface thereof and a plurality of seventh bump electrodes on a seventh surface thereof;
preparing a logic chip including a plurality of eighth bump electrodes on a eighth surface thereof;
preparing a wiring substrate including a plurality of connection pads thereon;
mounting the interposer chip over the wiring substrate so that the seventh bump electrodes electrically couple to the connection pads of the wiring substrate;
stacking the logic chip over the interposer chip so that the eighth bump electrodes electrically couple to corresponding ones of the sixth bump electrodes of the interposer chip; and
after the step of stacking the third memory chip over the second memory chip, stacking the chip stack over the interface chip so that the fourth bump electrodes electrically couple to corresponding ones of the sixth bump electrodes of the interposer chip via the second solder layers.

14. The method as claimed in claim 13, wherein the interface chip includes a first region and a second region that is different from the first region,
the logic chip is stacked over the first region of the interposer chip, and
the chip stack is stacked over the second region of the interposer chip.

15. The method as claimed in claim 11, wherein the first memory chip comprises a first memory circuit configuration on a side of the first surface,
the second memory chip comprises a second memory circuit configuration on a side of the second surface,
the third memory chip comprises a third memory circuit configuration on a side of the fourth surface, and
the first, second third memory circuit configurations are substantially identical.

16. The method as claimed in claim 11, wherein the second memory chip includes a plurality of first through electrodes, the third bump electrodes are electrically coupled to the second bump electrodes via the first through electrodes, and
the third memory chip includes a plurality of second through electrodes, the fifth bump electrodes are electrically coupled to the fourth bump electrodes via the second through electrodes.

17. The method as claimed in claim 15, wherein the first memory chip is larger in thickness than each of the second and third memory chips.

18. The method as claimed in claim 11, further comprising:
after the step of stacking the third memory chip over the second memory chip, supplying an under-fill material in the chip stack, a first gap between the first and second memory chips and a second gap between the second and third memory chips are filled by the under-fill material at the same time.

19. The method as claimed in claim 11, wherein the second memory chip includes a first insulation resin film on the third surface, a gap between the first and second memory chips is filled by the first insulation resin film, by the step of stacking the second memory chip over the first memory chip, and
the third memory chip includes a second insulation resin film on the fifth surface, a gap between the second and third memory chips is filled by the second insulation resin film, by the step of stacking the third memory chip over the second memory chip.

20. The method as claimed in claim 11, wherein the second solder layers are larger in thickness that the third solder layers.
